(19) United States
(12) Patent Application Publication
(10) Pub. No.: US 2014/0008763 A1
(43) Pub. Date: Jan. 9, 2014

(54) DISTRIBUTED SUBSTRATE TOP CONTACT FOR MOSCAP MEASUREMENTS

(71) Applicants: Salil Mujumdar, San Jose, CA (US); Amol Joshi, Sunnyvale, CA (US)

(72) Inventors: Salil Mujumdar, San Jose, CA (US); Amol Joshi, Sunnyvale, CA (US)

(73) Assignee: Intermolecular, Inc., San Jose, CA (US)

(21) Appl. No.: 13/544,710

(22) Filed: Jul. 9, 2012

(51) Int. Cl. H01L 29/92; H01L 21/02

(52) U.S. Cl. 257/535; 438/381; 257/E29.343; 257/E21.011

(57) ABSTRACT

Capacitor device structures can be fabricated on a substrate including multiple separate first electrodes and a common distributed second electrode. The second electrode can be common to the multiple first electrodes and can be distributed in a shape of a grid interdigitating the multiple first electrodes. The distributed nature of the second electrode can replace the substrate backside as the bottom electrode and can reduce the device parasitic characteristics. In some embodiments, the capacitor device structures can be used in a high productivity combinatorial process, wherein the distributed nature of the second electrode can make the test structures more tolerant to misalignment.

### TECHNICAL FIELD

Provided are methods and device structures for process developments, and more specifically for combinatorial methods of test measurements for gate stacks.

### BACKGROUND OF THE INVENTION

Advances in semiconductor processing have demanded ever-increasing high functional density with continuous size scaling. This scaling process has led to the adoption high-k gate dielectrics and metal gate electrodes in metal gate stacks in semiconductor devices.

High-k gate dielectrics can offer a way to scale down the equivalent oxide thickness of the gate dielectric with acceptable gate leakage current. The use of high-k gate dielectrics is often accompanied by a metal gate electrode, to screen the remote phonons in the high-k gate dielectrics, which can degrade the channel mobility. Also gate poly depletion can affect the device operation and performance. Metal gate electrodes further have an advantage of higher electrical conductance, as compared to poly gates, and thus can improve signal propagation times.

The manufacturing of high-k dielectric devices entails the integration and sequencing of many unit processing steps, with potential new process developments, since in general, high-k gate dielectrics are much more sensitive to process conditions than silicon dioxide. Simpler processing methods for simple device structures can be employed in R&D for large scale screening of materials and process conditions. For example, MOSCAP (metal oxide semiconductor capacitor) devices are well-known and have been used for years in microelectronics for electrical testing of dielectrics. To create a capacitor electrode on a substrate, a shadow mask is typically used in a deposition process of a conductive material. The MOSCAP devices can be tested to evaluate different device characteristics such as interface states, flat band voltage, which can affect subsequent fabrication processes, and consequently the performance of the device structures. The precise sequencing and integration of the unit processing steps enables the formation of functional devices meeting desired performance metrics such as power efficiency, signal propagation, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as integrated circuits. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single monolithic substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

HPC processing techniques have been successfully adapted to wet chemical processing such as etching and cleaning. HPC processing techniques have also been successfully adapted to deposition processes such as physical vapor deposition (PVD), atomic layer deposition (ALD), and chemical vapor deposition (CVD). HPC processing techniques have also been adapted to shadow mask MOSCAP device test measurements.

Hence, there is a need to apply high productivity combinatorial techniques to the improvements of MOSCAP device test structures.

### SUMMARY OF THE DESCRIPTION

In some embodiments, device test structures are provided including multiple first electrodes and a common second electrode. The first electrodes can be formed on a surface of a substrate, for example, in an equal spacing pattern. The second electrode can also be formed on the substrate surface, can be common to the multiple first electrodes, and can be distributed in a shape of a grid interdigitating the first electrodes. Each first electrode and the common second electrode can correspond to a test device, for example, a first electrode and the second electrode can contact two sides of a dielectric layer to form a capacitor structure that includes the first electrode formed on an insulator on the second electrode. The top distributed nature of the second electrode can replace the substrate backside as the bottom electrode, and can reduce the device parasitic characteristics.

In some embodiments, methods to form device test structures are provided, which include forming multiple separated first electrodes and a common distributed second electrode. A dielectric layer can be formed on a substrate, followed by the multiple first electrodes, which are formed on the dielectric layer. The common electrode can be formed, for example, on the dielectric layer, and can be distributedly interdigitating the first electrodes. The second electrode also contacts the opposite side of the dielectric layer, forming a capacitor structure including the dielectric layer having two sides contacting the first and second electrodes. The first and second electrodes can all be formed on the substrate surface, potentially facilitating the device testing process, since two electrodes of a test device are in the vicinity of each other.

In some embodiments, provided are high productivity combinatorial (HPC) methods and systems for forming device test structures, which include multiple separated first electrodes and a common distributed second electrode. The distributed nature of the second electrode can make the test structures more tolerant to misalignment in the combinatorial process, potentially improving yield and productivity.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 illustrates a schematic diagram for implementing combinatorial processing and evaluation using primary, secondary, and tertiary screening.

FIG. 2 is a simplified schematic diagram illustrating a general methodology for combinatorial process sequence integration that includes site isolated processing and/or conventional processing according to some embodiments.

FIG. 3 illustrates a schematic diagram of a substrate that has been processed in a combinatorial manner.

FIG. 4 illustrates a schematic diagram of a combinatorial wet processing system according to some embodiments.

FIG. 5 illustrates a simplified schematic diagram illustrating a sputter chamber configured to perform combinatorial processing.

FIGS. 6A-6B illustrate examples of a large and small area ALD or CVD showerheads used for combinatorial processing.

FIGS. 7A-7B illustrate a schematic example of capacitor structures having a distributed second electrode according to some embodiments.

FIG. 8 illustrates a flowchart for screening metal gate stacks according to some embodiments.

FIGS. 9A-9B illustrate an example of capacitor structures having a distributed second electrode according to some embodiments.

FIGS. 10A-10B illustrate another example of capacitor structures having a distributed second electrode according to some embodiments.

FIGS. 11A-11K illustrate illustrative cross sections of a fabrication sequence of a capacitor device for electrical testing according to some embodiments.

FIG. 12 illustrates a flow chart corresponded to the fabrication sequence of FIGS. 11A-11K.

FIG. 13A-13D illustrates examples of distributed electrodes for multiple capacitor structures according to some embodiments.

FIGS. 14A-14B illustrate an example of measurement according to some embodiments.

FIGS. 15A-15I illustrate illustrative cross sections of another fabrication sequence of a capacitor device for electrical testing according to some embodiments.

FIGS. 16A-16B illustrate an example of spot misalignment according to some embodiments.

### DETAILED DESCRIPTION OF THE DISCLOSURE

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

In some embodiments, provided is a distributed top electrode for multiple capacitor devices. Multiple capacitor devices can be fabricated on a substrate, with each capacitor device including a dielectric layer contacting two electrodes. The two electrodes can be formed on the top surface of the substrate, facilitate the probing action since the two electrodes can be in the viewing area of the test system.

In some embodiments, the multiple capacitor devices include multiple separate first electrodes and a common distributed second electrode. The first electrodes are separated from each other, and are unique for each capacitor device. The second electrode can be common to the multiple capacitor devices, and can be distributed to be in close proximity to the first electrodes. For example, the second electrode can be distributed on the surface of the substrate in a shape of a grid interdigitating the first electrodes. The distributed nature of the second electrode can replace the substrate backside as the bottom electrode. The distributed second electrode can also reduce the device parasitic characteristics for the multiple capacitor devices, since the distributed nature of the second electrode allows it to be formed near the first electrodes.

In some embodiments, the first and second electrodes can be top electrodes, e.g., fabricated on the top surface of the substrate. In the present description, the term “first electrode” is mostly used to identify the individual electrodes of the capacitor devices, meaning each capacitor device includes a first electrode that is electrically isolated from the first electrodes of other capacitor devices. The term “second electrode” is mostly used to identify the common electrode of the capacitor devices, meaning the second electrode can be the electrode of multiple capacitor devices.

In some embodiments, the distributed top electrode for multiple capacitor devices is provided in a combinatorial method to performed electrical testing, for example, from metal gate stacks including a metal electrode layer disposed on a high-k gate dielectric layer. The metal gate stacks can be fabricated using a shadow mask process, or can be fabricated as lithography patterned MOSCAP structures with field oxide isolation between the capacitor devices.

In the following description, methods for evaluating electrical data are illustrated using simple planar structures and process flows. Those skilled in the art will appreciate that the description and teachings to follow can be readily applied to any simple or complex testing methodology. The drawings are for illustrative purposes only and do not limit the application of the present invention.

“Combinatorial Processing” generally refers to techniques of differentially processing multiple regions of one or more substrates. Combinatorial processing generally varies materials, unit processes or process sequences across multiple regions on a substrate. The varied materials, unit processes, or process sequences can be evaluated (e.g., characterized) to determine whether further evaluation of certain process sequences is warranted or whether a particular solution is suitable for production or high volume manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

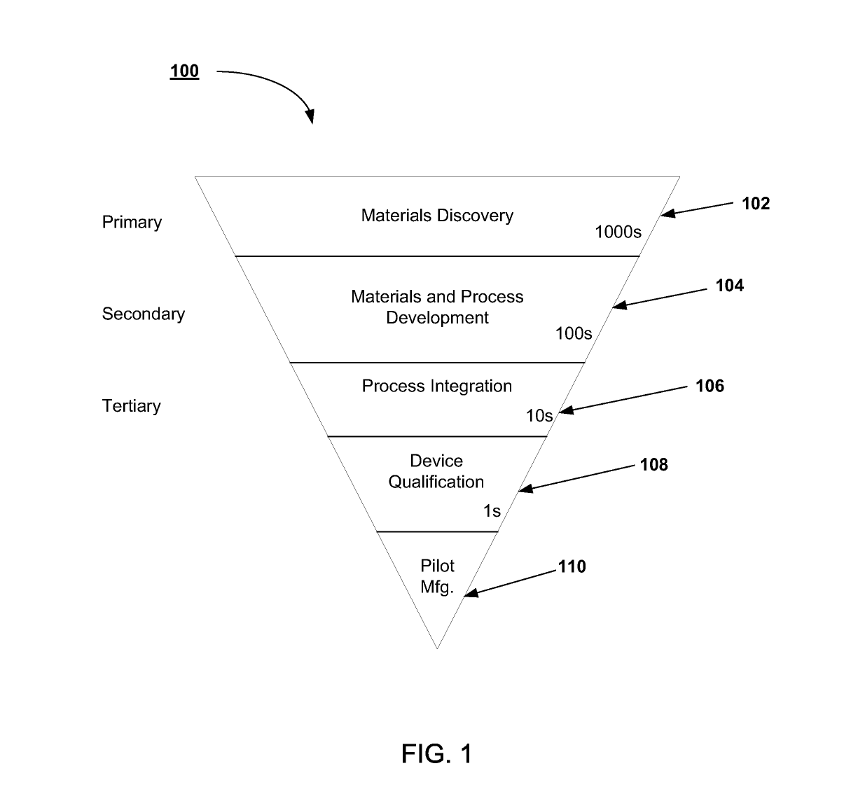

FIG. 1 illustrates a schematic diagram for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of high-k device fabrication process with metal gate by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a high-k device. A global optimum sequence order is therefore derived, and as part of this derivation, the unit processes, unit process parameters and materials used in the unit process operations of the optimum sequence order are also considered.

The embodiments described further analyze a portion or sub-set of the overall process sequence used to manufacture a semiconductor device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate, which are equivalent to the structures formed during actual production of the high-k device. For example, such structures may include, but would not be limited to, high-k dielectric layers, metal gate layers, spacers, or any other series of layers or unit processes that create an intermediate structure found on semiconductor devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

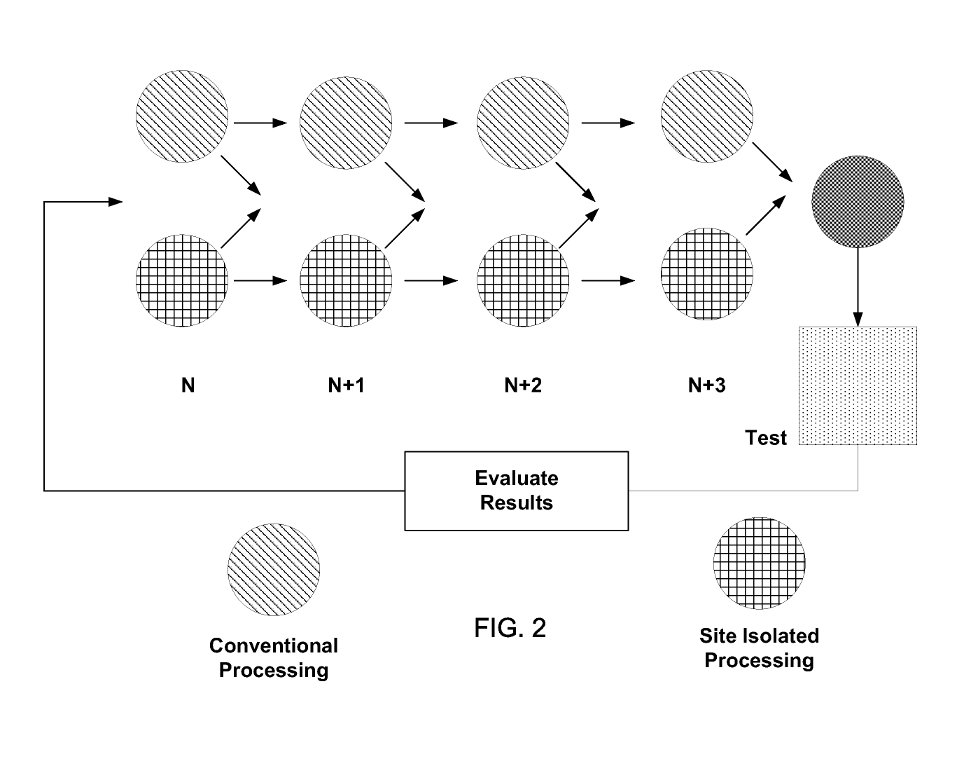

FIG. 2 is a simplified schematic diagram illustrating a general methodology for combinatorial process sequence integration that includes site isolated processing and/or conventional processing according to some embodiments. In some embodiments, the substrate is initially processed using conventional process N. In some embodiments, the substrate is then processed using site isolated process N+1. During site isolated processing, an HPC module may be used, such as the HPC module described in U.S. patent application Ser. No. 11/352,077 filed on Feb. 10, 2006, which is incorporated herein by reference for purposes of describing HPC modules. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in semiconductor manufacturing may be varied.

As mentioned above, within a region, the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

In some embodiments, capacitor testing structures are provided to evaluate materials and processes, for example, to identify dielectric constant values or leakage current characteristics of dielectric materials. Advanced semiconductor devices can employ novel materials such as metal gate electrodes and high-k dielectrics, which include dielectric materials having a dielectric constant greater than that of silicon dioxide. Typically high-k dielectric materials include aluminum oxide, hafnium oxide, zirconium oxide, tantalum oxide, titanium oxide, or their alloys such as hafnium silicon oxide or zirconium silicon oxide. Metal gate materials typically include a refractory metal or a nitride of a refractory metal, such as titanium nitride, titanium aluminum nitride, or titanium lanthanum nitride. Different high-k dielectric materials exhibit different dielectric constants and different leakage currents, together with different integration behavior with metal gate materials, leading to the need to screen the various high-k dielectric and metal gate materials to meet device performance levels.

In some embodiments, methods are provided to form capacitor structures on a substrate including forming a common electrode to the capacitor structures, which can be distributed to be in the vicinity of the other electrodes. In some embodiments, combinatorial workflow is provided for evaluating high-k dielectric and metal gate materials using capacitor designs with a distributed common electrode. High productivity combinatorial processing can be a fast and economical technique for electrically screening high-k dielectric and metal gate materials to determine their proper process integration in advanced semiconductor devices, achieving improved transistor performance through the incorporation of novel high-k dielectric and metal gate materials. The distributed electrode can improve yield by being tolerant to serious misalignment, for example, of the site isolated regions.

Combinatorial processing can be used to produce and evaluate different materials, chemicals, processes, process and integration sequences, and techniques related to semiconductor fabrication. For example, combinatorial processing can be used to determine optimal processing parameters (e.g., power, time, reactant flow rates, temperature, etc.) of dry processing techniques such as dry etching (e.g., plasma etching, flux-based etching, reactive ion etching (RIE)) and dry deposition techniques (e.g., physical vapor deposition (PVD), chemical vapor deposition (CVD), atomic layer deposition (ALD), etc.). Combinatorial processing can be used to determine optimal processing parameters (e.g., time, concentration, temperature, stirring rate, etc.) of wet processing techniques such as wet etching, wet cleaning, rinsing, and wet deposition techniques (e.g., electroplating, electroless deposition, chemical bath deposition, etc.).

FIG. 3 illustrates a schematic diagram of a substrate that has been processed in a combinatorial manner. A substrate, 300, is shown with nine site isolated regions, 302A-302I, illustrated thereon. Although the substrate 300 is illustrated as being a generally square shape, those skilled in the art will understand that the substrate may be any useful shape such as round, rectangular, etc. The lower portion of FIG. 3 illustrates a top down view while the upper portion of FIG. 3 illustrates a cross-sectional view taken through the three site isolated regions, 302G-302I. The shading of the nine site isolated regions illustrates that the process parameters used to process these regions have been varied in a combinatorial manner. The substrate may then be processed through a next step that may be conventional or may also be a combinatorial step as discussed earlier with respect to FIG. 2.

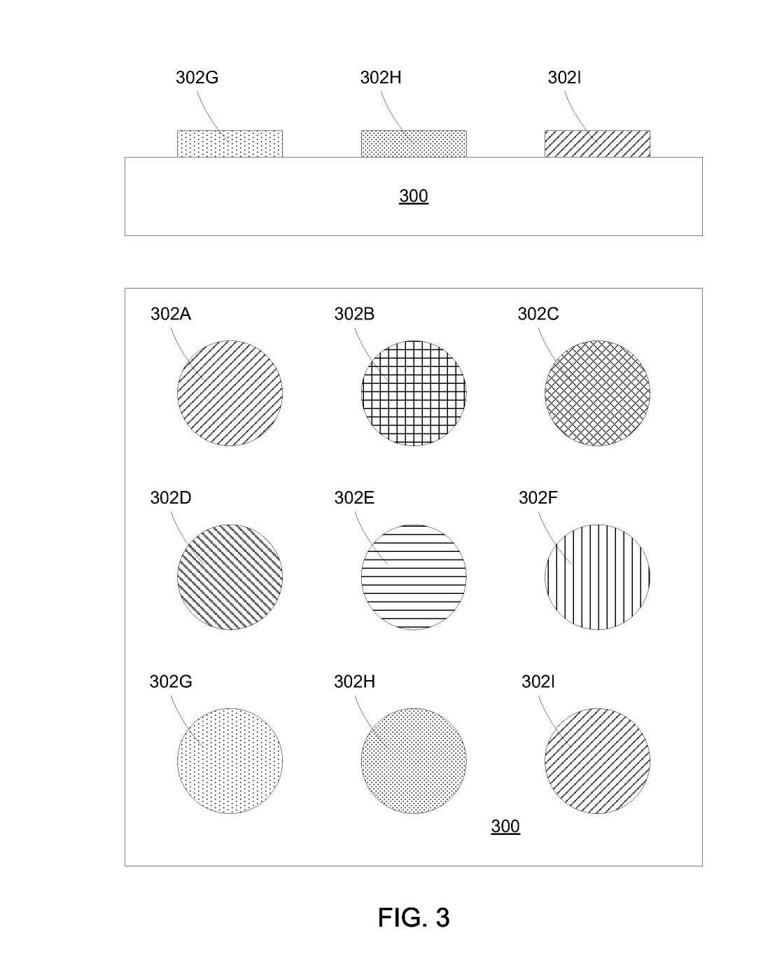

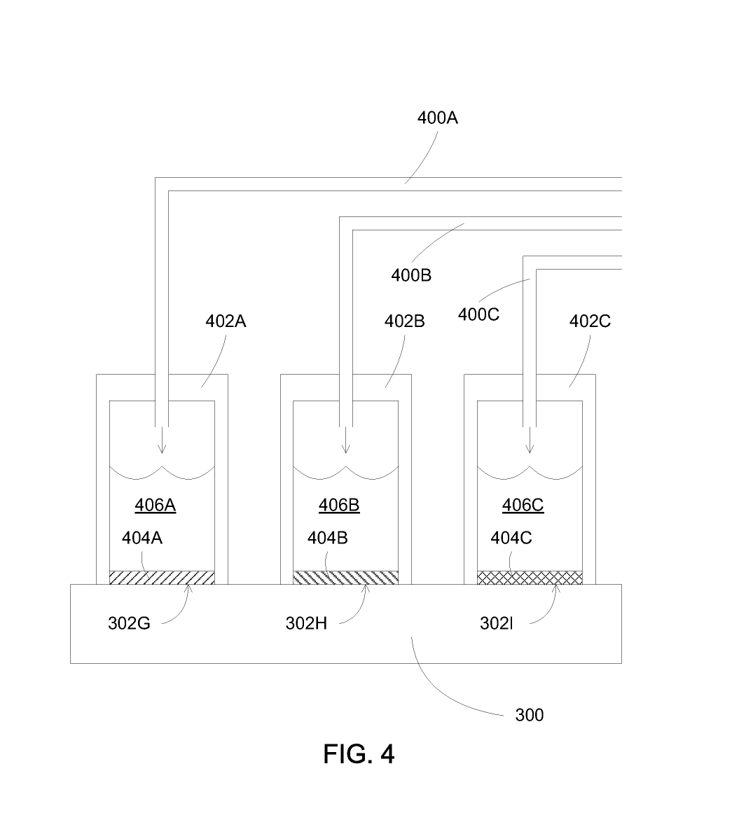

FIG. 4 illustrates a schematic diagram of a combinatorial wet processing system according to some embodiments. A combinatorial wet system may be used to investigate materials deposited by solution-based techniques. Those skilled in the art will realize that this is only one possible configuration of a combinatorial wet system. FIG. 4 illustrates a cross-sectional view of substrate, 300, taken through the three site isolated regions, 302G-302I similar to the upper portion of FIG. 3. Solution dispensing nozzles, 400a-400c, supply different solution chemistries, 406A-406C, to chemical processing cells, 402A-402C. FIG. 4 illustrates the deposition of a layer, 404A-404C, on respective site isolated regions. Although FIG. 4 illustrates a deposition step, other solution-based processes such as cleaning, etching, surface treatment, surface functionalization, etc. may be investigated in a combinatorial manner. The solution-based treatment can be customized for each of the site isolated regions.

In some embodiments, the dielectric layer is formed through a deposition process, such as chemical vapor deposition (CVD), atomic layer deposition (ALD), or physical vapor deposition (PVD). The metal electrode layer can be formed by PVD, CVD or ALD through a shadow mask or by a lithography patterning process.

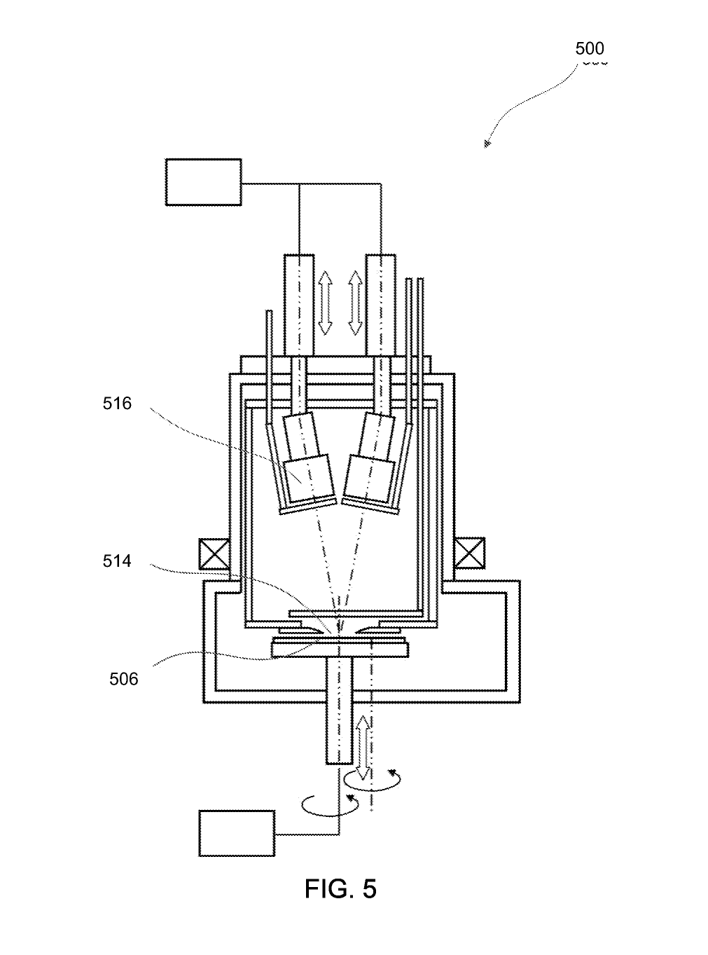

FIG. 5 illustrates a simplified schematic diagram illustrating a sputter chamber configured to perform combinatorial processing. The sputter system 500 generally includes a process chamber, one or more sputtering sources, and a transport system capable of positioning the substrate such that any area of the substrate can be exposed to sputtered material. The apparatus can further include an aperture positioned under each sputtering source, with the aperture oriented normal to the substrate and located adjacent to but not touching the substrate. The aperture typically has an opening smaller than the substrate so that discrete regions of the substrate can be subjected to distinct process conditions in a combinatorial manner. However, there is no particular limit on the size of the aperture. Typical apertures can range from a minimum of about 10 mm in one dimension, and can be square, round, or rectangular, for example. For combinatorial processing, the apertures are small enough such that films can be deposited on a plurality of site-isolated regions on a substrate. For high deposition rate sputtering to coat an entire substrate, the aperture can be up to approximately full substrate size.

The process chamber provides a controlled atmosphere so that sputtering can be performed at any gas pressure or gas composition necessary to perform the desired combinatorial processing. Typical processing gases include argon, oxygen, hydrogen, or nitrogen. However, additional gases can be used as desired for particular applications.

The transport system includes a substrate support capable of controlling substrate temperature up to about 550 C, and applying a bias voltage of a few hundred volts.

In the sputter system 500, a plurality of sputtering sources 516 are positioned at an angle so that they can be aimed through a single aperture 514 to a site-isolated region on a substrate 506. The sputtering sources 516 are positioned about 100-300 mm from the aperture 514 to ensure uniform flux to the substrate within the site-isolated region. Details of the combinatorial PVD system are described in U.S. patent application Ser. No. 12/027,980 filed on Feb. 7, 2008 and U.S. patent application Ser. No. 12/028,643 filed on Feb. 8, 2008, which are herein incorporated by reference for purposes of describing combinatorial PVD system.

In some embodiments, a deposition process can be performed in the sputter system 500 in a combinatorial manner. The combinatorial deposition process generally includes exposing a first site-isolated region of a surface of a substrate to material from a sputtering source under a first set of process parameters, and exposing a second site-isolated region of a surface of the substrate to material from a sputtering source under a second set of process parameters. During exposure of the surface of the substrate to the sputtering source, the remaining area of the substrate is not exposed to the material from the sputtering target, enabling site-isolated deposition of sputtered material onto the substrate. The combinatorial process can further include exposing three or more site-isolated regions of the substrate to material from a sputtering source under distinct sets of process parameters. The combinatorial process can further include depositing additional layers onto any site-isolated region to build multi-layered structures if desired. In this manner, a plurality of process conditions to deposit one or a plurality of layers can be explored on a single substrate under distinct process parameters.

The process parameters that can be combinatorially varied generally include sputtering parameters, sputtering atmosphere parameters, substrate parameters, or combinations thereof. Sputtering parameters typically include exposure times, power, sputtering target material, target-to-substrate spacing, or a combination thereof. Sputtering atmosphere parameters typically include total pressure, carrier gas composition, carrier gas flow rate, reactive gas composition, reactive gas flow rate, or combinations thereof. The reactive gas flow rate can be set to greater than or equal to zero in order to vary the reactive gas composition in an inert carrier gas. The substrate parameters typically include substrate material, surface condition (e.g., roughness), substrate temperature, substrate bias, or combinations thereof.

Substrates can be a conventional round 200 mm, 300 mm, or any other larger or smaller substrate/wafer size. In other embodiments, substrates may be square, rectangular, or other shape. One skilled in the art will appreciate that substrate may be a blanket substrate, a coupon (e.g., partial wafer), or even a patterned substrate having predefined regions. In some embodiments, a substrate may have regions defined through the processing described herein.

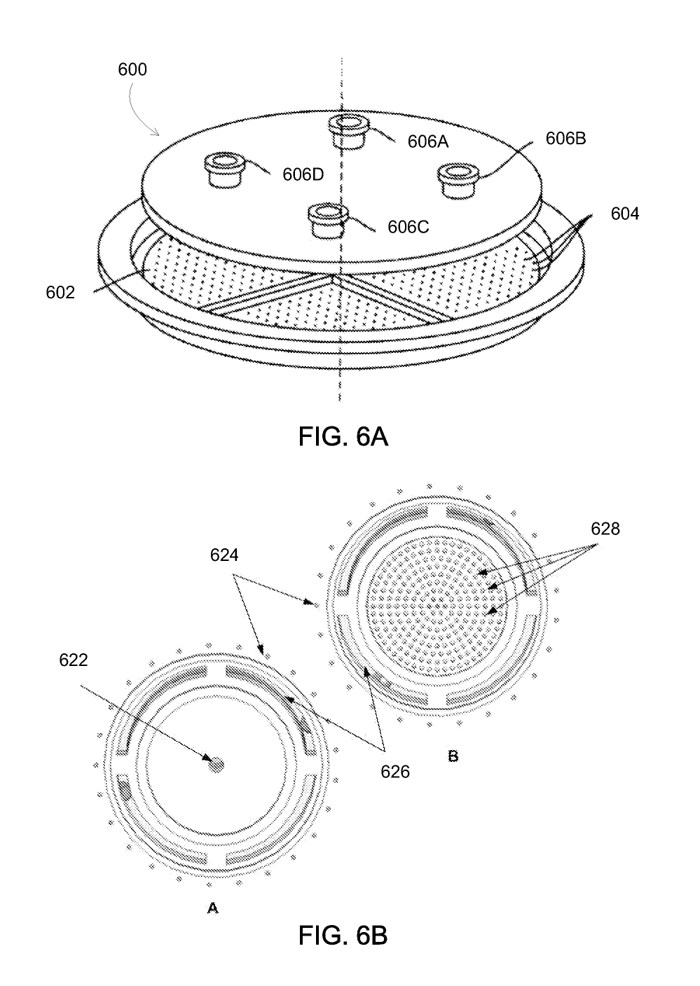

FIGS. 6A-6B illustrate examples of a large and small area ALD or CVD showerheads used for combinatorial processing. Details of large area showerhead and its use may be found in U.S. patent application Ser. No. 12/013,729 entitled “Vapor Based Combinatorial Processing” filed on Jan. 14, 2008 and claiming priority to Provisional Application No. 60/970,199 filed on Sep. 5, 2007, U.S. patent application Ser. No. 12/013,759 entitled “Vapor Based Combinatorial Processing” filed on Jan. 14, 2008 and claiming priority to Provisional Application No. 60/970,199 filed on Sep. 5, 2007, and U.S. patent application Ser. No. 12/205,578 entitled “Vapor Based Combinatorial Processing” filed on Sep. 5, 2008 which is a Continuation Application of the U.S. patent application Ser. No. 12/013,729 and claiming priority to Provisional Application No. 60/970,199 filed on Sep. 5, 2007, all of which are herein incorporated by reference for purposes of describing showerheads for HPC processing. Details of small area showerhead and its use may be found in U.S. patent application Ser. No. 13/302,097 entitled “Combinatorial Deposition Based on a Spot Apparatus” filed on Nov. 22, 2011, and U.S. patent application Ser. No. 11/468,422 entitled “Combinatorial Approach for Screening of ALD Film Stacks” filed on Nov. 22, 2011, all of which are herein incorporated by reference.

The large area ALD or CVD showerhead, 600, illustrated in FIG. 6A includes four regions, 602, used to deposit materials on a substrate. As an example, in the case of a round substrate, four different materials and/or process conditions could be used to deposit materials in each of the four quadrants of the substrate (not shown). Precursor gases, reactant gases, purge gases, etc. are introduced into each of the four regions of the showerhead through gas inlet conduits 606a-606b. For simplicity, the four regions, 602, of showerhead, 600, have been illustrated as being a single chamber. Those skilled in the art will understand that each region, 602, of showerhead, 600, may be designed to have two or more isolated gas distribution systems so that multiple reactive gases may be kept separated until they react at the substrate surface. Also for simplicity, on a single gas inlet conduit, 606a-606d, is illustrated for each of the four regions. Those skilled in the art will understand that each region, 602, of showerhead, 600, may have multiple gas inlet conduits. The gases exit each region, 602, of showerhead, 600, through holes, 604, in the bottom of the showerhead. The gases then travel to the substrate surface and react at the surface to deposit a material, etch an existing material on the surface, clean contaminants found on the surface, react with the surface to modify the surface in some way, etc. The showerhead illustrated in FIG. 6A is operable to be used with any of a CVD, plasma enhanced CVD (PECVD), ALD, or plasma enhanced ALD (PEALD) technology.

As discussed previously, showerhead, 600, in FIG. 6A results in a deposition (or other process type) on a relatively large region of the substrate. In this example, a quadrant of the substrate. To address the limitations of the combinatorial showerhead illustrated in FIG. 6A, small spot showerheads have been designed as illustrated in FIG. 6B. FIG. 6B illustrates a bottom view of two examples of a small spot showerhead apparatus in accordance with some embodiments. The small spot showerhead configuration, A, illustrated in FIG. 6B includes a single gas distribution port, 622, in the center of the showerhead for delivering reactive gases to the surface of the substrate. The small size of the small spot showerhead and the behavior of the technologies envisioned to use this showerhead ensure that the uniformity of the process on the substrate is adequate using the single gas distribution port. However, the small spot showerhead configuration, B, illustrated in FIG. 6B includes a plurality of gas distribution ports, 628, for delivering reactive gases to the surface of the substrate. This configuration can be used to improve the uniformity of the process on the substrate if required.

Each small spot showerhead is surrounded by a plurality of purge holes, 624. The purge holes introduce inert purge gases (i.e. Ar, N₂, etc.) around the periphery of each small spot showerhead to insure that the regions under each showerhead can be processed in a site isolated manner. The gases, both the reactive gases and the purge gases, are exhausted from the process chamber through exhaust channels, 626, that surround each of the showerheads. The combination of the purge holes, 624, and the exhaust channels, 626, ensure that each region under each showerhead can be processed in a site isolated manner. The diameter of the small spot showerhead (i.e. the diameter of the purge ring) can vary between about 40 mm and about 100 mm. Advantageously, the diameter of the small spot showerhead is about 65 mm.

Using a plurality of small spot showerheads as illustrated in FIG. 6B allows a substrate to be processed in a combinatorial manner wherein different parameters can be varied as discussed above. Examples of the parameters include process material composition, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, etc.

A combination of large area and small area showerhead can be used. For example, using a large area showerhead, the substrate can be generally divided into four quadrants. Within each quadrant, small area showerheads can be used, for example, three site isolated regions can be processed using small spot showerheads, yielding twelve site isolated regions on the substrate. Therefore, in this example, twelve independent experiments could be performed on a single substrate.

In some embodiments, provided are test capacitor structures with each capacitor including a dielectric layer contacting a first electrode and a second electrode. The first and second electrodes can be formed on a same side of the substrate, for example, on the top surface of the substrate. The first electrodes of the capacitor structures can be separated from each other, for example, to provide isolation between the capacitor structures and to allow testing of individual capacitor structures. The second electrodes of the capacitor structures can be connected to each other to form a common second electrode. In addition, the common second electrode can be distributed around the first electrodes so that at least a portion of the common second electrode is close to the individual first electrodes. For example, the common second electrode can surround the individual first electrodes, or can be interdigitated with the individual first electrodes.

The closeness of the first electrodes and different portions of the distributed second electrode can allow ease of measurement probing since the two electrodes of a capacitor device can be in the same view of an operator looking through a viewer of the probe testing system.

The closeness of the first electrodes and different portions of the distributed second electrode can reduce parasitic impedance, such as resistance or capacitance, between the first and second electrodes since the distance between the two electrodes can be adjusted through mask designing. For example, the distance between the two electrodes can be shorter as compared to using a substrate backside contact.

The closeness of the first electrodes and different portions of the distributed second electrode can improve HPC yield since even a serious misalignment of site isolated regions can still provide of measurable capacitor devices with the distributed common second electrode formed near the individual first electrodes.

In some embodiments, the capacitor structures having common distributed second electrode can provide electrical testing of semiconductor devices, for example, to identify compatible and appropriate materials for a metal gate stack of PMOS (p-type metal-oxide-semiconductor) or NMOS (n-type metal-oxide-semiconductor) transistors that can satisfy the device performance. The semiconductor devices can be MOS (metal-oxide-semiconductor) capacitors, including a metal electrode disposed on a high-k dielectric on a semiconductor substrate. In some embodiments, the MOS capacitors are patterned using a shadow mask, wherein the first and second electrodes are formed by PVD metal deposition process. In some embodiments, the MOS capacitors are patterned using known lithography techniques, having active areas isolated by patterned field oxide. The patterned MOS capacitors can be free of edge defects, having the field oxide protecting the active areas during and after the device fabrication processes. The patterned MOS capacitors can be free of probing damage, having the metal probe pads separated from the active areas. The active areas can be independent of the metal areas and can be uniform across the semiconductor substrate. The evaluation can be performed for multilayer metal stacks deposited in different tools such as ALD (atomic layer deposition) or PVD (physical vapor deposition) systems. In addition, the test chip can be designed with several repetitions of the same structures in different areas of the die, so the MOSCAP workflow can tolerate significant misalignment between the lithography defined dies and the combinatorial high-k and metal deposition. In the following description, MOSCAP structures are described in some embodiments, but the invention is not so limited, and can be used for evaluating any other device structures such as MOSFET (metal oxide semiconductor field effect transistor).

Advanced semiconductor devices can employ novel materials such as metal gate electrodes and high-k dielectrics, which include dielectric materials having a dielectric constant greater than that of silicon dioxide. Typically high-k dielectric materials include aluminum oxide, hafnium oxide, zirconium oxide, tantalum oxide, titanium oxide, or their alloys such as hafnium silicon oxide or zirconium silicon oxide. Metal gate materials typically include a refractory metal or a nitride of a refractory metal, such as titanium nitride, titanium aluminum nitride, or titanium lanthanum nitride. Different combinations of high-k dielectric and metal electrode materials, together with different process conditions, can exhibit different device characteristics, such as different effective work function values, and thus can require careful screening and evaluations to obtain proper materials and process conditions.

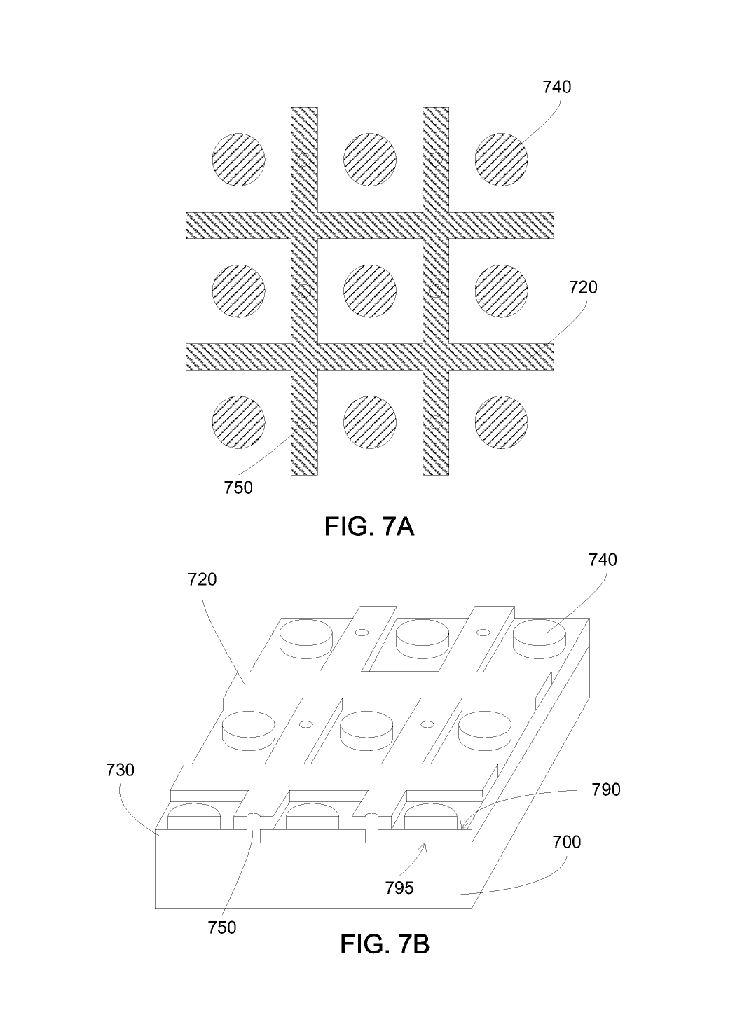

FIGS. 7A-7B illustrate a schematic example of capacitor structures having a distributed second electrode according to some embodiments. FIG. 7A shows a top view and FIG. 7B shows a perspective view of capacitor structures including individual first electrode 740 and a common distributed second electrode 720. The first electrode 740 and the second electrode 720 can contact two sides 790 and 795 of a dielectric layer 730, respectively, forming a capacitor structure. The common second electrode 720 is distributed around the first electrode 740, so that each capacitor structure can be electrical tested with a first electrode 740 and a nearby second electrode 720. The first and second electrodes can be formed on the top surface of the substrate 700, for example, to allow ease of probing. Via contact 750 can be provided to allow contact of the second electrode 720 with the bottom side 795 of the dielectric layer 730.

In some embodiments, the capacitor structures having a distributed second electrode can provide evaluation of potential impact of various metal gate stacks on transistor performance and reliability, including electrical testing of metal oxide semiconductor (MOS) capacitor structures. MOS capacitor structures can be quickly and economically fabricated, permitting evaluating potential device characteristics, such as effective work function, of various materials and process conditions with fast turn-around times. For example, flatband voltage measurements can provide information directly related to the performance of high-k dielectric, such as the presence of fixed charges, mobile charges or surface state charges in the high-k or at the high-k dielectric/semiconductor interface. Effective work function extraction can provide information on the threshold voltage of the metal/high-k gate stacks.

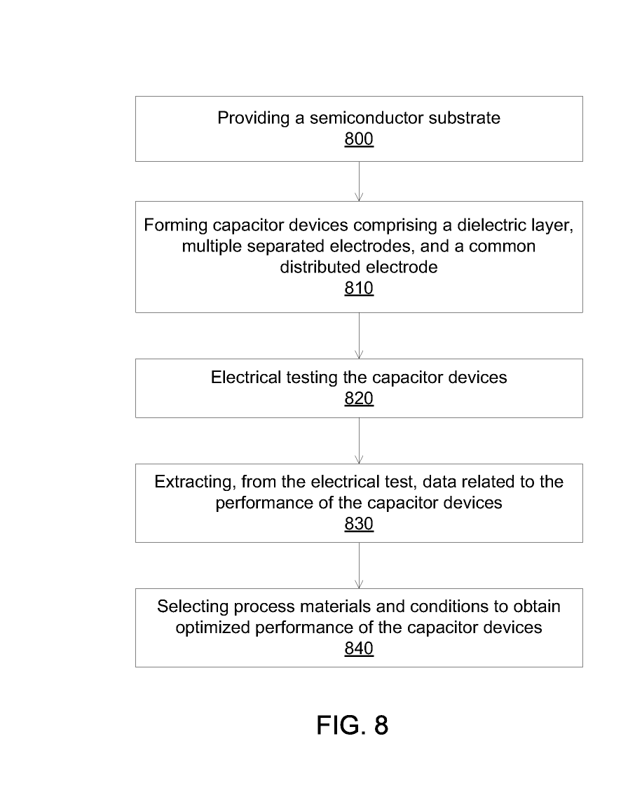

FIG. 8 illustrates a flowchart for screening metal gate stacks according to some embodiments. Different high-k dielectric materials, different metal materials, and/or different process conditions such as PVD or ALD deposition for the metal electrodes can be used to fabricate MOS capacitor structures, representing gate stacks of a transistor device. The electrical performance of the MOS capacitor devices can provide the effective work function of the metal gate stacks, permitting a quick ranking of various materials and process conditions. Poor performance high-k and metal combinations, together with sub-optimum process conditions can be identified and removed without the need to fabricate and test fully-operational devices.

In operation 800, a semiconductor substrate is provided. The semiconductor substrate can be a silicon-containing substrate, a germanium-containing substrate, an III-V or II-VI substrate, or any other substrate containing a semiconductor element. In operation 810, capacitor structures are fabricated, including forming a high-k dielectric layer on the substrate, multiple first electrodes and a common distributed second electrode. The common distributed second electrode can be formed so that at least a portion of the second electrode is near the first electrodes. In some embodiments, the second electrode is distributed so that a distance between a first electrode and the second electrode is shorter than between two first electrodes. The high-k dielectric layer can include a high-k dielectric material, such as aluminum oxide, hafnium oxide, zirconium oxide, tantalum oxide, titanium oxide, or their alloys such as hafnium silicon oxide or zirconium silicon oxide. The electrode layer can include a refractory metal or a nitride of a refractory metal, such as titanium nitride, titanium aluminum nitride, or titanium lanthanum nitride.

In some embodiments, multiple site isolation regions are processed on a substrate, with varying materials and process conditions for the different site isolated regions. In some embodiments, patterned capacitor device structures are fabricated, including lithographically defined active areas, and lithographically defined metal electrodes, aligned with the active areas.

In operation 820, the capacitor devices, including an electrode formed on a dielectric layer on the semiconductor substrate, are electrically tested, for example, by probing, e.g., contacting with probes, the first and second electrodes. The electrical tests can include a flatband voltage measurement, for example, to determine the presence of charges in the dielectric and at the dielectric/semiconductor interface. The electrical tests can include I-V and C-V measurements, including single curve or cycling testing, with varying sweep voltage range, sweep speed, or sweep frequency, which can offer possible correlation to the defect states.

In operation 830, data related to the performance of the capacitor device is extracted from the electrical test. For example, effective work function of the metal/high-k electrode stack can be extracted from the electrical tests. In operation 840, high-k materials, metal electrode materials and process conditions are selected based on a comparison of the device performance.

In some embodiments, the electrical testing of MOS devices can offer a list of process compatibility between multiple high-k and metal materials and process conditions of the devices, such as the deposition techniques of the high-k layer or the metal gate layer. This list can enable the optimum device fabrication process, at least with respect to the metal gate stack in a transistor device.

In some embodiments, variations of the metal gate stack in the capacitor devices can be used. For example, the capacitor devices can include different materials or process conditions of the high-k dielectric. The capacitor devices can include different materials or process conditions of the metal electrode. Other process conditions can also included, such as anneal conditions for the metal electrode layer.

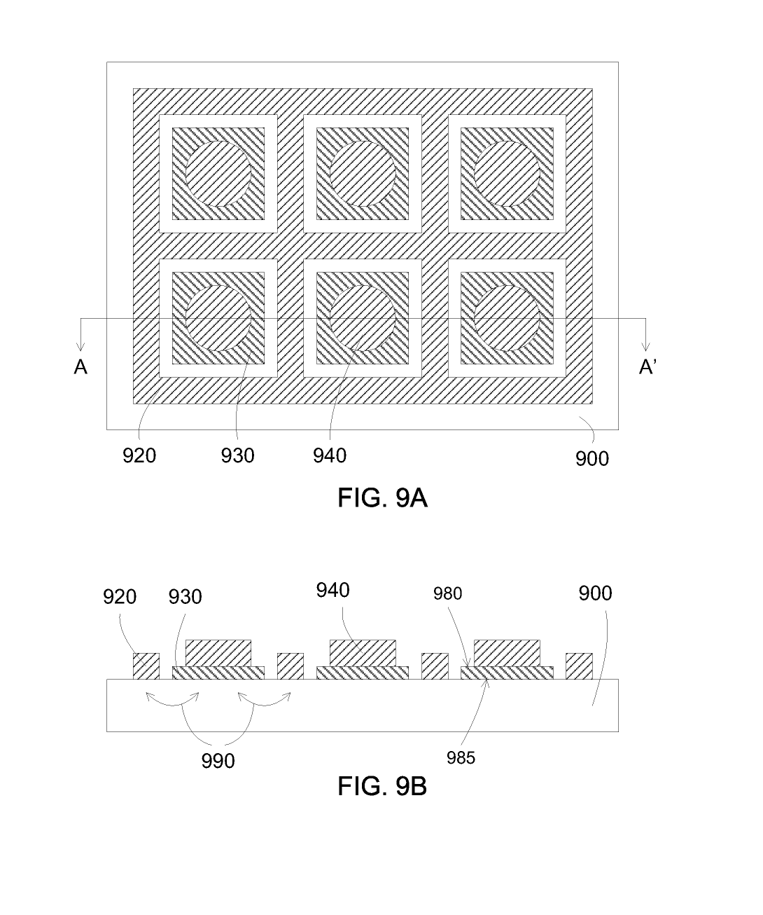

FIGS. 9A-9B illustrate an example of capacitor structures having a distributed second electrode according to some embodiments. FIG. 9A shows a top view and FIG. 9B shows a cross section view AA′ of capacitor structures including individual first electrode 940 and a common distributed second electrode 920. The common second electrode 920 is distributed around the first electrode 940.

In some embodiments, the dielectric layer 930 is formed under the first electrodes 940, with the area outside the first electrodes 940 etched away for the second electrode 920 contacting the substrate 900. The first electrode 940 and the second electrode 920 can contact two sides 980 and 985 of a dielectric layer 930, respectively, to form a capacitor structure. For example, the first electrode 940 contacts the top side of the dielectric layer 930. The second electrode 920 contacts the bottom side of the dielectric layer 930 through the substrate 900, for example, by paths 990. The electrodes 920 and 940 can be formed by deposition, e.g., PVD, through a shadow mask. The dielectric layer 930 can be formed by a blanket deposition, e.g., PVD or ALD, and then a portion of the blanket layer is etched away to form individual dielectric layers 930.

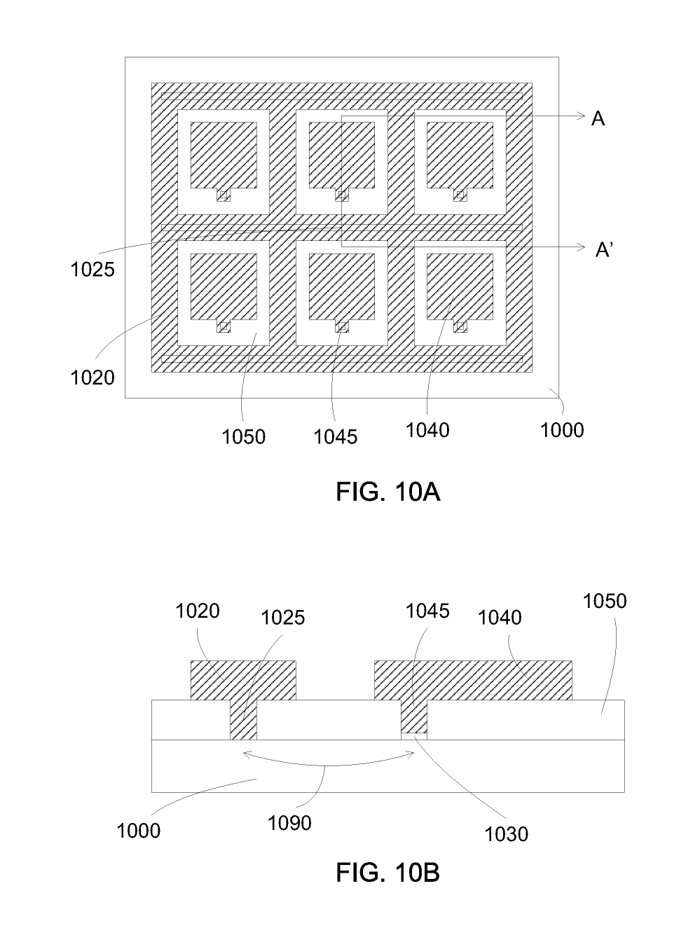

FIGS. 10A-10B illustrate another example of capacitor structures having a distributed second electrode according to some embodiments. FIG. 10A shows a top view and FIG. 10B shows a cross section view AA′ of capacitor structures including individual first electrode 1040 and a common distributed second electrode 1020. The common second electrode 1020 is distributed around the first electrode 1040.

In some embodiments, the dielectric layer 1030 is formed in an active area 1045, isolated and protected by a field oxide 1050. The field oxide 1050 can include via contact 1025, for example, for the second electrode 1020 to contact the substrate 1000. The first and second electrodes can include bond pad configuration for probing. For example, the first electrode 1040 includes a rectangular bond pad shape for probing, away from the active area 1045. The second electrode does not have any specific bond pad configuration, and can be probed at any open area. A first electrode 1040 and the second electrode 1020 can contact two sides of a dielectric layer 1030 to form a capacitor structure. For example, the first electrode 1040 contacts the top side of the dielectric layer 1030. The second electrode 1020 contacts the bottom side of the dielectric layer 1030 through the substrate 1000, for example, by paths 1090. The electrodes 1020 and 1040 can be formed by deposition, e.g., PVD or ALD, and patterned by a lithography process. The dielectric layer 1030 can be formed by a blanket deposition, e.g., PVD or ALD, and then a portion of the dielectric can be etched away to form via contacts 1025.

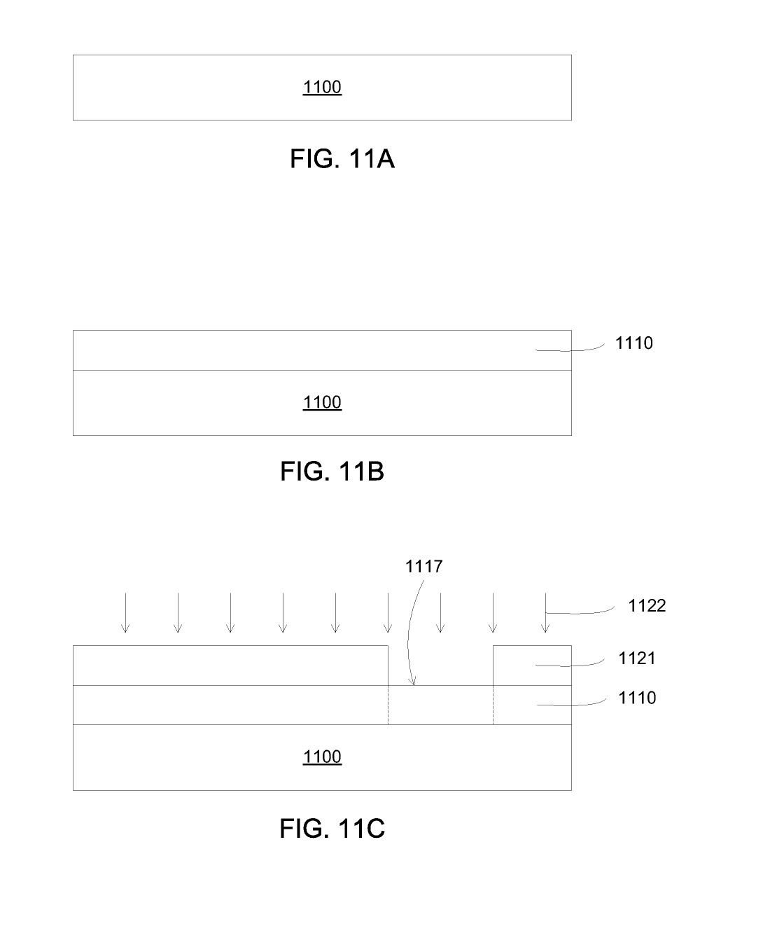

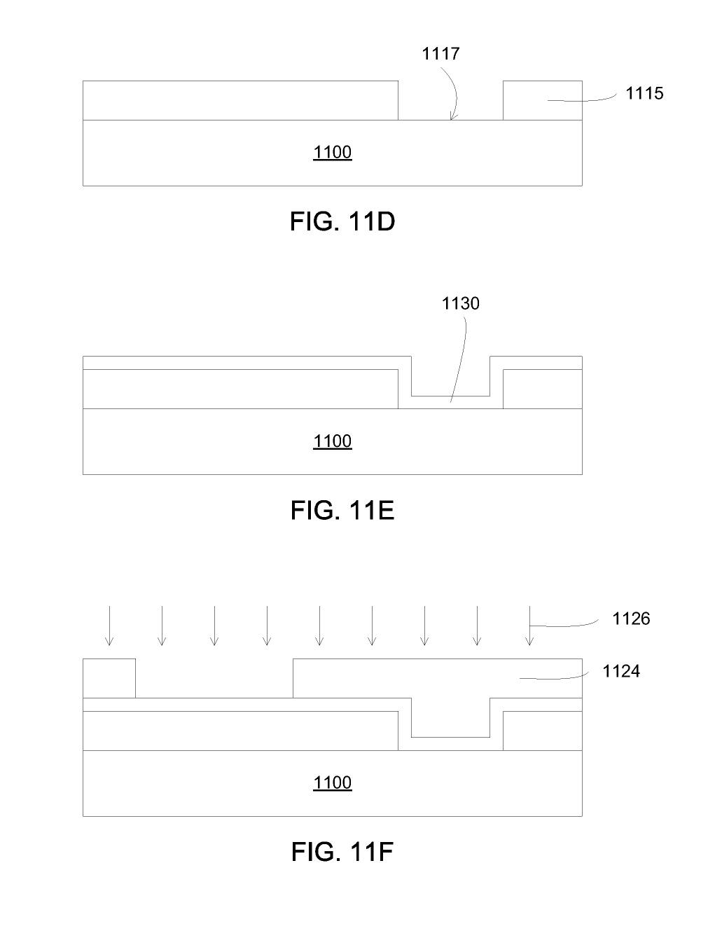

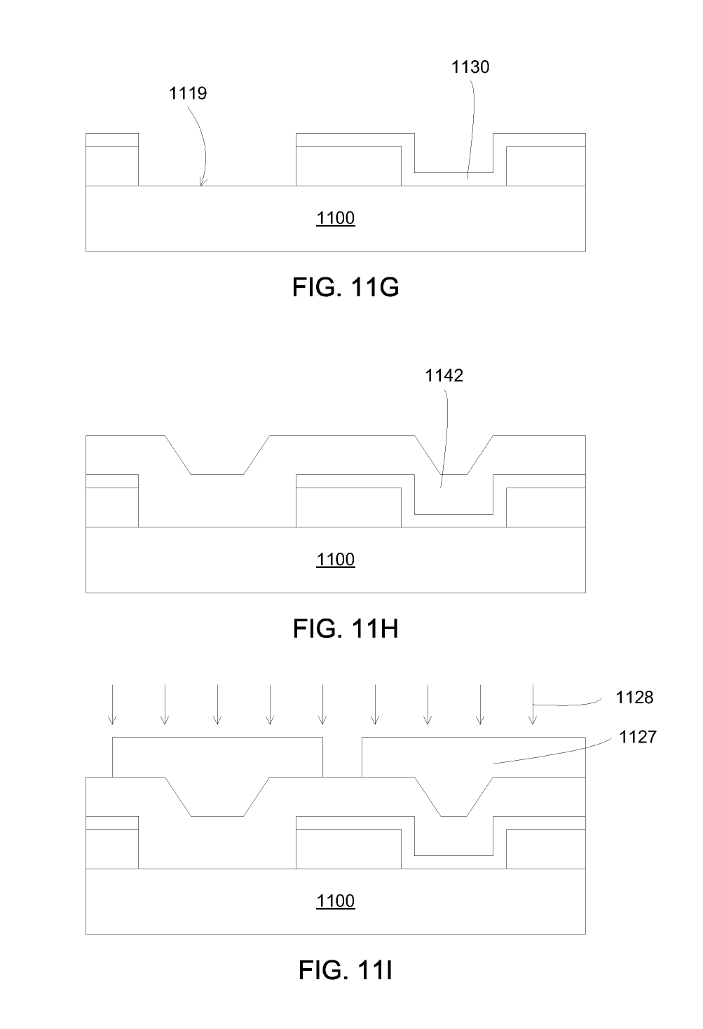

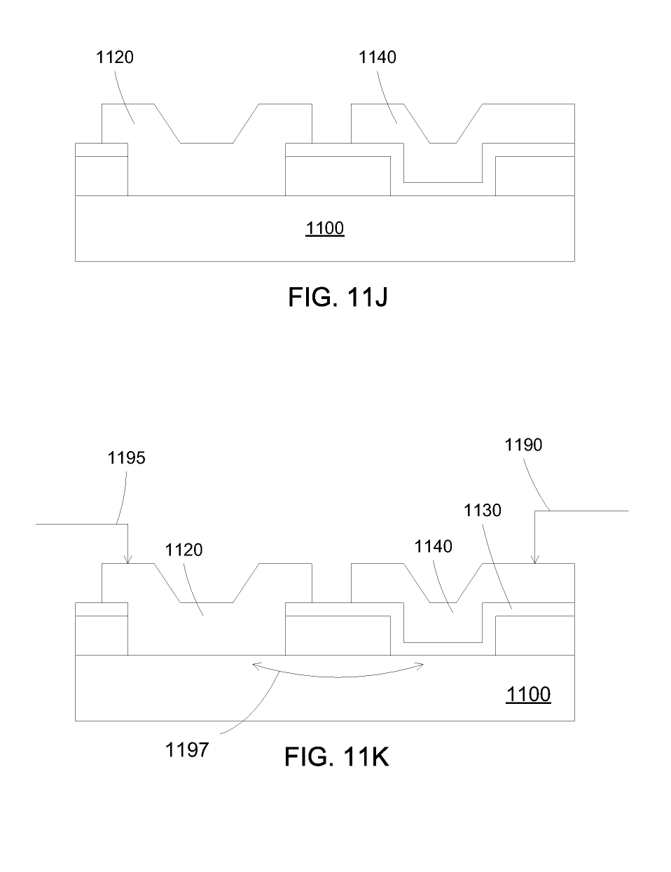

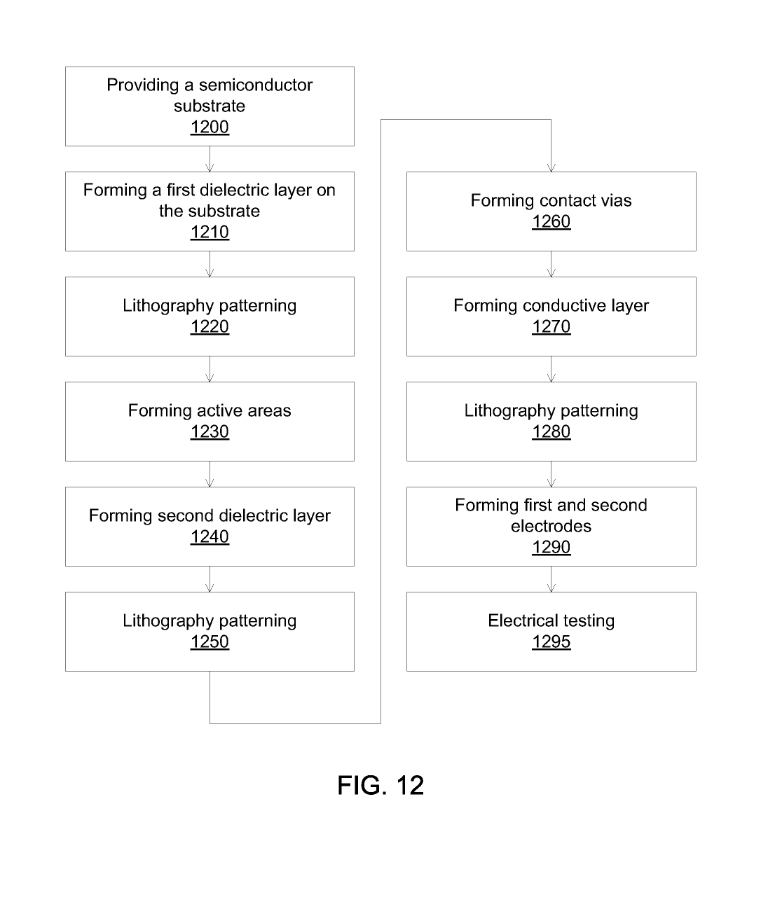

FIGS. 11A-11K illustrate example cross sections of a fabrication sequence of a capacitor device for electrical testing according to some embodiments. FIG. 12 illustrates a flow chart corresponded to the fabrication sequence of FIGS. 11A-11K, for example, for screening metal gate stacks according to some embodiments. The metal gate stack can be included in a capacitor structure with high-k dielectric and metal electrode, fabricated using photolithography process. The screening process can include electrical data testing, for example, effective work function extraction from the capacitor structures, to evaluate the feasibility of different metal gate stack materials and processes.

In FIG. 11A and corresponding operation 1200, a semiconductor substrate 1100 is provided. In FIG. 11B and corresponding operation 1210, a first dielectric layer, such as a field oxide 1110, is formed on the substrate, for example, by chemical vapor deposition (CVD) or thermally grown process. The thickness of the field oxide can be between about 100 to about 500 nm, and can serve as an isolation material for the capacitor devices.

In FIG. 11C and corresponding operation 1220, the field oxide layer 1110 is patterned to form active areas 1117. The active areas 1117 can be used to form dielectric layer for the capacitor devices. The active areas can have different sizes, for example, 1 μm×1 μm, 4 μm×4 μm, 8 μm×8 μm, 20 μm×20 μm, 100 μm×100 μm, 200 μm×200 μm, and 500 μm×500 μm. Other capacitor structures can be included, such as finger structures. Lithography processes can be used, for example, by spin coating the field oxide layer 1110 with a photoresist layer 1121. After exposing the photoresist layer 1121 to a light exposure through a mask, the photoresist layer 1121 forms an image of the mask pattern. An etch process 1122, for example, a plasma etch or a wet etch, can be performed to remove the portion of the field oxide that is not protected by the photoresist 1121.

In FIG. 11D and corresponding operation 1230, active areas 1117 are formed. For example, the photoresist layer 1121 is removed, and the mask pattern is transferred to the field oxide 1115. The etched portions of the field oxide 1115 form the active areas 1117.

In FIG. 11E and corresponding operation 1240, a second oxide layer, for example, a high-k dielectric layer 1130 such as a hafnium oxide layer, is formed in the active area. In some embodiments, the high-k dielectric layer can be formed in a combinatorial manner across the multiple site isolated regions, for example, with changing in deposition conditions or high-k materials. The first oxide layer can be formed by chemical vapor deposition (CVD), or by atomic layer deposition (ALD). Various dielectric materials can be used, for example, high-k dielectric materials or composite layer of silicon dioxide and high-k material.

In FIG. 11F and corresponding operation 1250, the field oxide layer and the high-k dielectric layer 1130 are patterned to form via contacts 1119. The via contacts 1119 can be used to form interconnection of the substrate with the second electrode of the capacitor devices. Lithography process can be used, for example, by spin coating the field oxide layer with a photoresist layer 1124. After exposing the photoresist layer 1124 to a light exposure through a mask, the photoresist layer 1124 forms an image of the mask pattern. An etch process 1126, for example, a plasma etch or a wet etch, can be preformed to remove the portion of the field oxide that is not protected by the photoresist 1124.

In FIG. 11G and corresponding operation 1260, via contacts 1119 are formed. For example, the photoresist layer 1124 is removed, and the mask pattern is transferred to the field oxide and the high-k layers. The etched portions of the field oxide and the high-k layers form the via contacts 1119.

In FIG. 11H and corresponding operation 1270, conductive layer 1142 is formed on the dielectric layers, e.g., the field oxide and the high-k layer, for example, by physical vapor deposition (PVD), chemical vapor deposition (CVD), or by atomic layer deposition (ALD). Various metal alloy materials can be used, for example, metal nitride materials or composite layer of metal electrode layer and polysilicon conductor layer.

In FIG. 11I and corresponding operation 1280, the conductive layer 1142 is patterned, aligned with the active areas 1117 and the via contacts 1119, to form first and second electrodes. Lithography process can be used, for example, by coating the conductive layer 1142 with a photoresist layer 1127. After exposing the photoresist layer 1127 to a light exposure through a mask, the photoresist layer 1127 forms an image of the mask pattern. An etch process 1128, for example, a plasma etch or a wet etch, can be performed to remove the portion of the metal electrode layer that is not protected by the photoresist 1127.

In FIG. 11J and corresponding operation 1290, the first and second electrodes are formed. For example, the photoresist layer 1127 is removed, and the mask pattern is transferred to the conductive layer to form first electrodes 1140 and second electrode 1120. A first electrode 1140, the high-k dielectric layer 1130, and the substrate 1100, contacted through the second electrode 1120, form a MOS capacitor device.

In FIG. 11K and corresponding operation 1295, the MOS capacitor device can be electrically tested, for example, by probing the first electrode 1140 with first probe 1190 and the second electrode 1120 with second probe 1195. The second electrode 1120 contacts the substrate, e.g., through path 1197, to form MOS capacitor structure, e.g., first electrode 1140, high-k dielectric 1130, substrate 1100, and second electrode 1120.

Different configurations can be used for the distributed second electrode. In some embodiments, the distributed second electrode can form a connected web, including many portions that are distributed near the multiple first electrodes. For example, each first electrode can have a portion of the second electrode disposed nearby. The first electrode and the nearby portion of the second electrode can include bond pad configuration for probing.

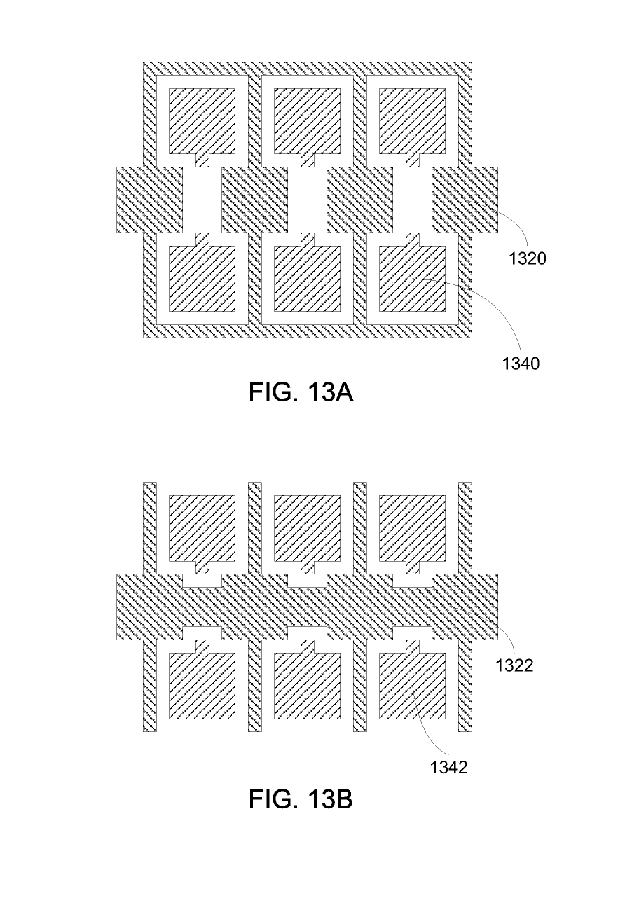

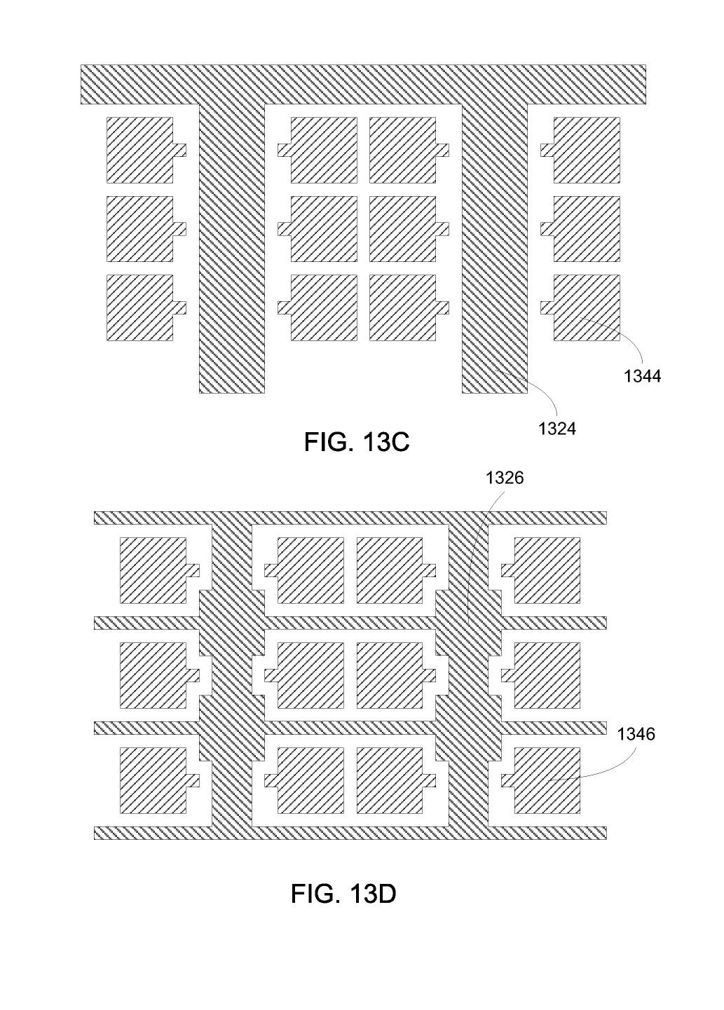

In some embodiments, the present invention discloses a second electrode that is configured to interdigitate multiple first electrodes. In the context of the present application, the term “interdigitate” provides that the second electrode is configured to be at a substantially similar distance to all of the multiple first electrodes. Examples of the second electrode interdigitating the multiple first electrodes can be seen in FIGS. 7A, 9A, 10A, and 13A-13D (to be described in detail in the following paragraphs). In FIG. 7A, second electrode 720 is distributed around multiple first electrodes 740. In FIGS. 9A and 10A, second electrode 920/1020 is distributed around multiple first electrodes 940/1040, including the outer periphery. In FIGS. 13A and 13B, second electrode 1320/1322 is distributed in lines individually separating multiple first electrodes 1340/1342. In FIGS. 13C and 13D, second electrode 1324/1326 is distributed in lines separating every two of multiple first electrodes 1344/1346. The examples are illustrative, and other configurations are within the scope of the present application, providing a second electrode that is distributed so that it can approach multiple first electrodes at a substantially similar distance.

FIG. 13A-13D illustrates examples of distributed electrodes for multiple capacitor structures according to some embodiments. In FIG. 13A, multiple individual first electrodes 1340 can be formed on a substrate. The first electrodes 1340 are separated from each other and can be formed in regular arrays on the substrate. The first electrode can include a bond pad, designed to be probed by a test probe. Near the bond pad is the active area, which covers the dielectric layer and is electrically connected to the bond pad. The active area can be formed at a boundary of the bond pad, for example, to prevent damages to the active area during the probing procedure. The second electrode 1320 can be connected, and distributed surrounding the first electrodes 1340. The second electrode can include bond pad configurations, for example, a bond pad is formed near the bond pad of the first electrode, providing two nearby bond pads for ease of probing.

In FIG. 13B, the second electrode 1322 can be interdigitating the first electrodes 1342, including bond pad configurations near the bond pads of the first electrodes. In FIG. 13C, the second electrode can include large line, for example, at the size of the bond pad, thus allowing probing directly on the second electrode. The first electrodes can be formed back-to-back, thus the second electrode can interdigitate every two columns of the first electrodes. In FIG. 13D, the second electrode can include bond pads, together with large interconnect lines. In general, the second electrode can be configured to minimize the surface area, and can also provide bond pads, or places for probing, near the first electrodes.

In some embodiments, combinatorial workflow is provided for evaluating electrical data, such as effective work function, from gate stacks, to provide optimized process conditions for gate stack formation, such as for metal gate stack using high-k dielectrics. High productivity combinatorial processing can be a fast and economical technique for electrically screening materials and process conditions to determine their suitability and possible side effects on the transistor performance, avoiding potentially costly device process development through proper selection of high-k and metal electrode materials and fabrication processes. For example, the electrical testing can include at least one of an I-V measurement, a C-V measurement, a flatband voltage shift measurement, or an effective work function measurement.

The capacitor structures and the fabrication methods to form the capacitor structures having distributed electrode can be fully compatible with HPC process flow. Further, the methods can be highly tolerant to HPC PVD/Wet etch spot misalignments, since the common electrode is distributed over the whole die. In addition, the distributed electrode can be formed as top contact, thus can eliminate the need of using the chuck as a second contact, which can reduce parasitic effects on electrical measurements. Further, the top distributed electrode can eliminate the need of applying silver paste at the backside of the substrate, which can result in a better vacuum distribution over the substrate. The process flow can be shorter with the elimination of the silver paste application. The top distributed electrode can also facilitate the electrical testing calibration, for example, open or short calibration, since both the probes are always in the field of view.

In some embodiments, the second electrode can be formed as a top electrode, and distributed in the shape of a grid over the whole die. The top contact can eliminate the need of using the chuck as a second contact, which can reduce the parasitic components of the capacitor devices. The distributed nature of the contact can make it more tolerant to HPC PVD/Wet etch spot misalignments, for example, as compared to a non-distributed substrate top contact. In addition, the grid nature of the substrate top contact can result in the presence of the distributed electrode in close proximity to all active pads, e.g., the other electrodes of the capacitor devices, over the whole die. This can simplify the calibrations and measurements of the capacitor devices, since both the probes, e.g., the probes for the two electrodes of the capacitor devices, are always in the field of view. Further, open and short calibration can be relatively simple, which can be performed by moving the probes over short distances.

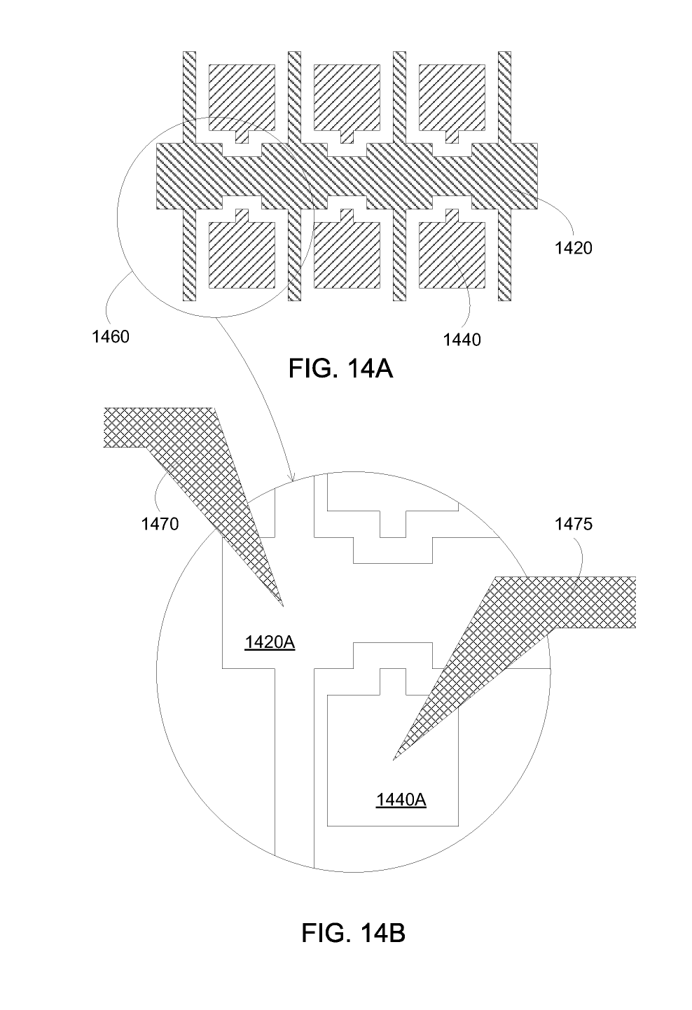

FIGS. 14A-14B illustrate an example of measurement according to some embodiments. In FIG. 14A, multiple first electrodes 1440 are formed on a substrate. A common top distributed electrode 1420 is also formed, interdigitating the first electrodes 1440. A probe view 1460 can focus on the substrate, viewing the capacitor device having first electrode 1440A and second electrode 1420A. Since the two electrodes are formed in vicinity of each other, they can be seen in the field of view of the probe view 1460. Probes 1470 and 1475 can also be viewed through the probe view 1460, allowing ease of setting of measurement probes. Further, shorted calibration can be easily performed, for example, by moving the probe 1475 toward the common distributed electrode 1420A.

In some embodiments, the top distributed electrode can assist in simplifying the process flow of the capacitor fabrication. For example, via contact formation can be eliminated, leaving the top distributed electrode also disposed on the high-k dielectric. Since the top distributed electrode can be much larger than the active area, and since the high-k dielectric can be very thin, the contribution of the high-k dielectric in contact with the top distributed electrode can be negligible as compared to the contribution of the high-k dielectric in the active area.

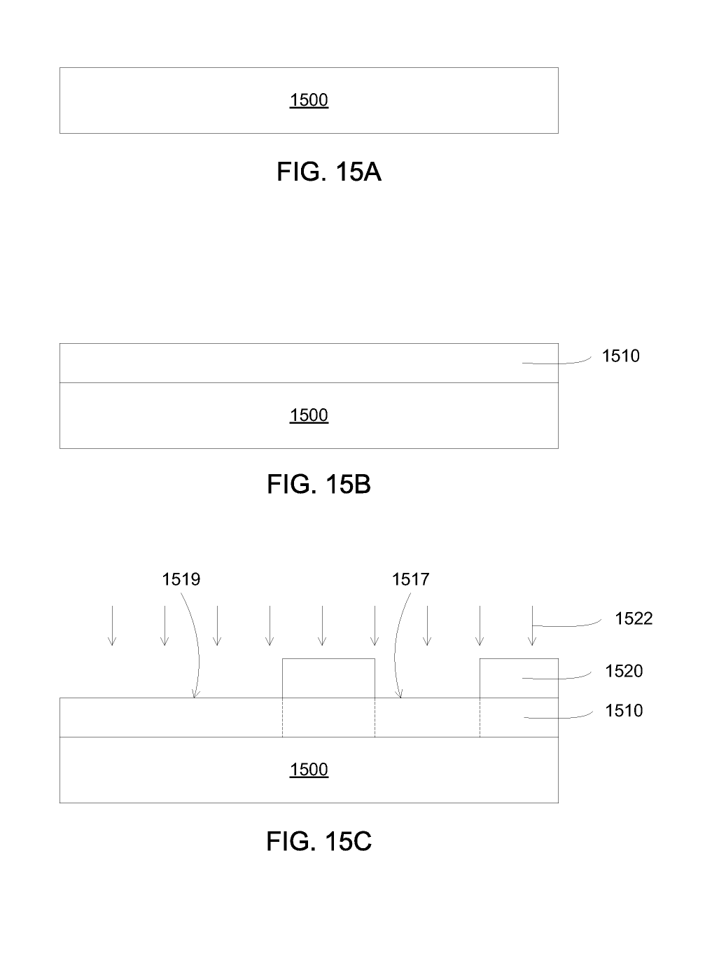

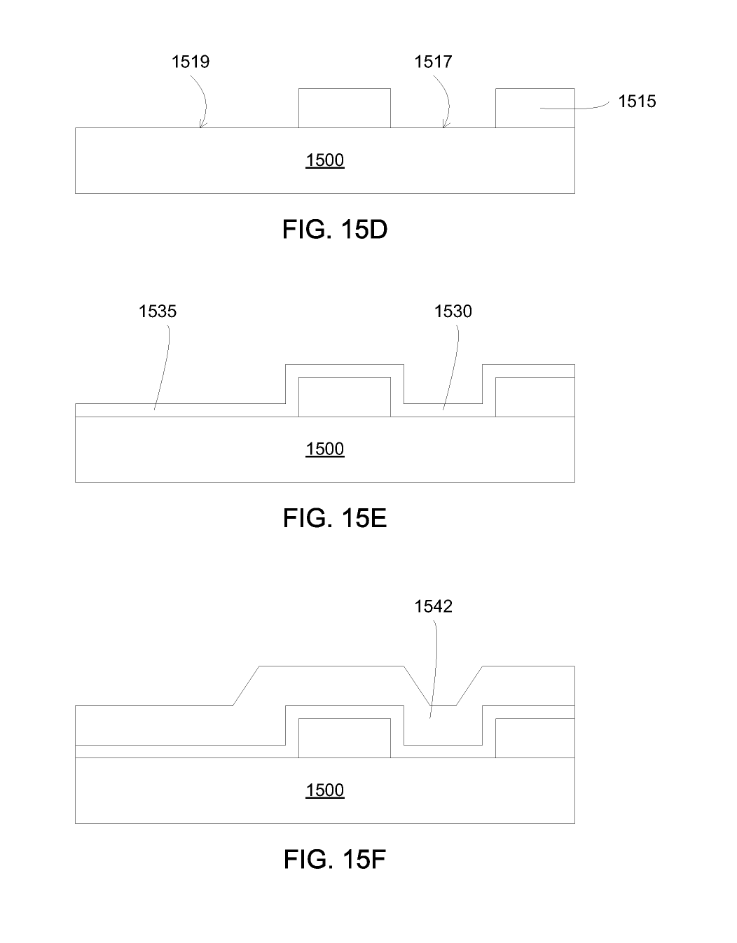

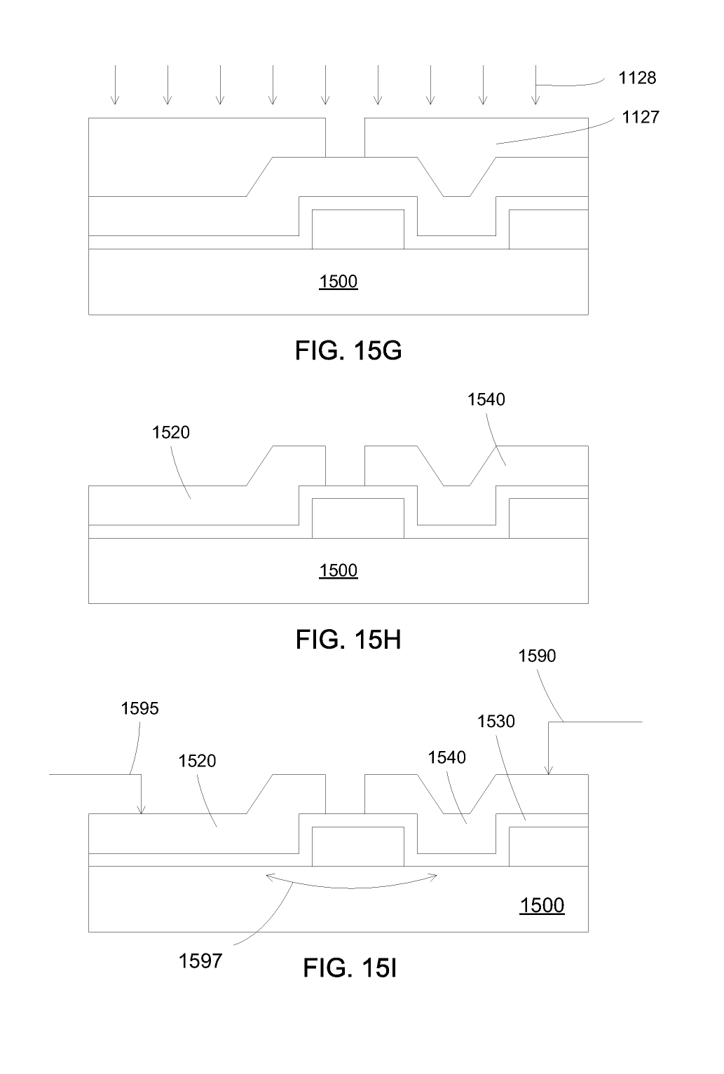

FIGS. 15A-15I illustrate illustrative cross sections of another fabrication sequence of a capacitor device for electrical testing according to some embodiments. The metal gate stack can be included in a capacitor structure with high-k dielectric and metal electrode, fabricated using photolithography process. The screening process can include electrical data testing, for example, effective work function extraction from the capacitor structures, to evaluate the feasibility of different metal gate stack materials and processes.

In FIG. 15A, a semiconductor substrate 1500 is provided. In FIG. 15B, a first dielectric layer, such as a field oxide 1510, is formed on the substrate, for example, by chemical vapor deposition (CVD) or thermally grown process. The thickness of the field oxide can be between about 100 to about 500 nm, and can serve as an isolation material for the capacitor devices.

In FIG. 15C, the field oxide layer 1510 is patterned to form active areas 1517 and contact areas 1519 for the top distributed second electrode. The active areas 1517 can be used to form dielectric layer for the capacitor devices. The active areas can have different sizes, for example, 1 μm×1 μm, 4 μm×4 μm, 8 μm×8 μm, 20 μm×20 μm, 100 μm×100 μm, 200 μm×200 μm, and 500 μm×500 μm. Other capacitor structures can be included, such as finger structures.

The contact areas can be large, for example, large enough to accommodate the top distributed electrode. For example, the contact areas can be at least 1000× larger than the active areas, and can be larger than 500× as compared to the active areas. The large contact areas can reduce or eliminate the contribution of the dielectric under the top distributed electrode.

Lithography processes can be used, for example, by spin coating the field oxide layer 1510 with a photoresist layer 1520. After exposing the photoresist layer 1520 to a light exposure through a mask, the photoresist layer 1520 forms an image of the mask pattern. An etch process 1522, for example, a plasma etch or a wet etch, can be performed to remove the portion of the field oxide that is not protected by the photoresist 1520.

In FIG. 15D, active areas 1517 and contact areas 1519 are formed. For example, the photoresist layer 1520 is removed, and the mask pattern is transferred to the field oxide 1515. The etched portions of the field oxide 1515 form the active areas 1517 and contact areas 1519.

In FIG. 15E, a second oxide layer, for example, a high-k dielectric layer such as a hafnium oxide layer 1530, is formed in the active areas and the contact areas. In some embodiments, the high-k dielectric layer can be formed in a combinatorial manner across the multiple site isolated regions, for example, with changing in deposition conditions or high-k materials. The first oxide layer can be formed by chemical vapor deposition (CVD), or by atomic layer deposition (ALD). Various dielectric materials can be used, for example, high-k dielectric materials or composite layer of silicon dioxide and high-k material.

In FIG. 15F, conductive layer 1542 is formed on the dielectric layers, e.g., the field oxide and the high-k layer, for example, by physical vapor deposition (PVD), chemical vapor deposition (CVD), or by atomic layer deposition (ALD). Various metal alloy materials can be used, for example, metal nitride materials or composite layer of metal electrode layer and polysilicon conductor layer.

In FIG. 15G, the conductive layer 1542 is patterned, aligned with the active areas 1517 and the contacts 1519, to form first and second electrodes. The first electrodes individually cover the active areas. The second electrode can be a top distributed electrode, covering the contact areas and distributing interdigitating the first electrodes. Lithography process can be used, for example, by coating the conductive layer 1542 with a photoresist layer 1527. After exposing the photoresist layer 1527 to a light exposure through a mask, the photoresist layer 1527 forms an image of the mask pattern. An etch process 1528, for example, a plasma etch or a wet etch, can be performed to remove the portion of the metal electrode layer that is not protected by the photoresist 1527.

In FIG. 15H, the first and second electrodes are formed. For example, the photoresist layer 1527 is removed, and the mask pattern is transferred to the conductive layer to form first electrodes 1540 and second electrode 1520. A first electrode 1540, the high-k dielectric layer 1530, and the substrate 1500, contacted through the second electrode 1520, form a MOS capacitor device. The high-k dielectric layer 1530 is also present under the second electrode 1520, but since the area of the contact is much larger than the areas of the active areas, the effect can be negligible. The size of the second electrode can be larger than about 1000 times as compared to that of a first electrode. For example, the size of the first electrode can be about a few micron squares, and the size of the second electrode can be about 1000 micron squares.

In FIG. 15I, the MOS capacitor device can be electrically tested, for example, by probing the first electrode 1540 with first probe 1590 and the second electrode 1520 with second probe 1595. The second electrode 1520 contacts the substrate, e.g., through path 1597, to form MOS capacitor structure, e.g., first electrode 1540, high-k dielectric 1530, substrate 1500, and second electrode 1520.

In some embodiments, the distributed top contact, e.g., the second electrode, can be present over the whole die, and can have a large enough area to make a very good contact, due to high leakage, with the substrate. The distributed nature of the distributed top contact can improve yield, for example, by continuing to function, even though, a part of it ceases to work due to spot misalignments in the HPC flow.

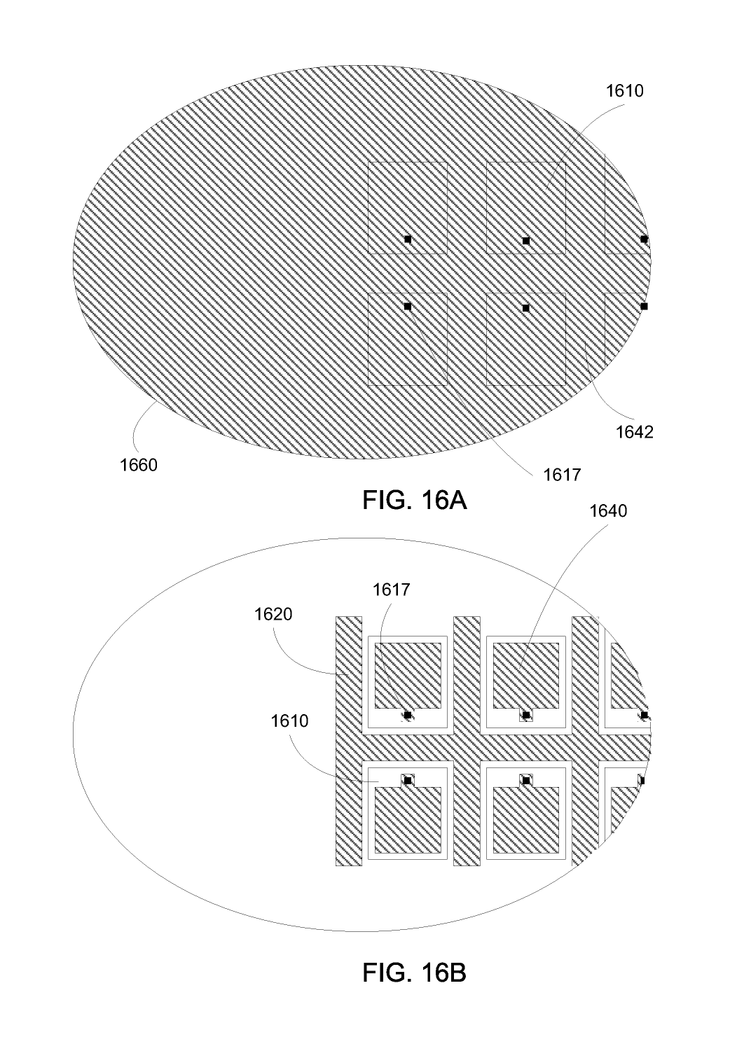

FIGS. 16A-16B illustrate an example of spot misalignment according to some embodiments. In FIG. 16A, a site isolation region 1660 is shown, for example, to form a conductive layer 1642. The conductive layer 1642 can be deposited by PVD or ALD process, filling the site isolation region 1660. Under the conductive layer, active areas 1617 and field isolation areas 1610 can already formed, for example, by etching through a blanket field oxide layer. In some embodiments, a cross section of the configuration can be shown in FIGS. 15D-15F, with the conductive layer 1642 corresponded to the conductive layer 1542, the active areas 1617 corresponded to the active areas 1517, and the field isolation areas 1610 corresponded to the field isolation 1515. As shown, the site isolation region 1660 is greatly misaligned, for example, shifted from the proper position in which the active areas and via contacts are centered within the site isolated region 1660.

In FIG. 16B, the patterning step of the conductive layer 1642 is performed, for example, which corresponds to the cross section shown in FIG. 15H. The conductive layer 1642 can be patterned to form multiple first electrodes 1640 and a common distributed second electrode 1620. The common distributed electrode can be distributed in the vicinity of the first electrodes, for example, interdigitating the first electrodes. With the distributed second electrode distributed near the first electrodes, at least some of the capacitor structures can be formed and measured, even with the gross misalignment of the site isolated region 1660.

Although the foregoing examples have been described in some detail for purposes of clarity of understanding, the invention is not limited to the details provided. There are many alternative ways of implementing the invention. The disclosed examples are illustrative and not restrictive.

What is claimed is:

1. A method comprising:
providing a substrate, wherein the substrate comprises a surface;
forming a first dielectric layer on the substrate;
forming a plurality of first electrodes on the first dielectric layer; and
forming a second electrode on the first dielectric layer, wherein the area of the second electrode is at least 1000 times larger than the area of a first electrode of the plurality of the first electrodes,
wherein the second electrode is distributed interdigitating the plurality of first electrodes.

2. The method of claim 1, wherein the second electrode is distributed around the plurality of first electrodes so that each first electrode is at a same distance to a portion of the second electrode.

3. The method of claim 1, wherein the second electrode is distributed around the first electrodes so that a distance between one of the first electrodes and the second electrode is equal to or smaller than the distance between any two of the plurality of first electrodes.

4. The method of claim 1, further comprising, before forming the first dielectric layer:
forming a second dielectric layer on the surface of the substrate; and
patterning the second dielectric layer to form a plurality of first open areas in the second dielectric layer.

5. The method of claim 4, further comprising, before forming the first and second electrodes:
forming at least one second open area in the second dielectric layer.

6. The method of claim 5, wherein forming the first and second electrodes comprises:
forming a conductive layer on the first dielectric layer; and
patterning the conductive layer to form the plurality of first electrodes and the second electrode.

7. The method of claim 1, further comprising:
annealing the substrate after forming the electrodes.

8. A combinatorial method comprising:
providing a substrate, wherein the substrate comprises a surface;
forming a first dielectric layer on the substrate in multiple site isolated regions;
forming a plurality of first electrodes on the first dielectric layer in the multiple site isolated regions; and
forming a second electrode on the first dielectric layer in the multiple site isolated regions, wherein the area of the second electrode is at least 1000 times larger than the area of a first electrode of the plurality of the first electrodes,
wherein the second electrode is distributed interdigitating the plurality of first electrodes,
wherein at least one characteristic in the multiple site isolated regions is varied in a combinatorial manner.

9. The method of claim 8, wherein the at least one characteristic in the multiple site isolated regions comprises a thickness of the first dielectric or a material of the first and second electrodes.

10. The method of claim 8, wherein the second electrode is distributed around the first electrodes so that each first electrode is at a same distance to a portion of the second electrode.

11. The method of claim 8, wherein the second electrode is distributed around the first electrodes so that the distance between a first electrode and the second electrode is equal or smaller than the distance between two first electrodes.

12. The method of claim 8 further comprising, before forming the first dielectric layer:
forming a second dielectric layer on the surface of the substrate; and
patterning the second dielectric layer to form a plurality of first open areas in the second dielectric layer.

13. The method of claim 12 further comprising, before forming the first and second electrodes:
forming at least one second open area in the second dielectric layer.

14. The method of claim 13 wherein forming the first and second electrodes comprises:
forming a conductive layer on the first dielectric layer; and
patterning the conductive layer to form the plurality of first electrodes and the second electrode.

15. A device structure comprising:
a substrate, wherein the substrate comprises a surface;
a dielectric layer disposed on the substrate;
a plurality of first electrodes disposed on the dielectric layer; and
a second electrode disposed on the dielectric layer,
wherein the area of the second electrode is at least 1000 times larger than the area of a first electrode of the plurality of the first electrodes,
wherein the second electrode is distributed interdigitating the plurality of first electrodes.

16. The device structure of claim 15, wherein the entire second electrode is in contact with a surface of the dielectric layer.

17. The device structure of claim 15, wherein the second electrode is in contact with a surface of the substrate through an opening in the dielectric layer.

18. The device structure of claim 15, wherein the second electrode is distributed so that each first electrode is at a similar distance to the second electrode.

19. The device structure of claim 15 wherein the second electrode is distributed so that the distance between a first electrode and the second electrode is equal to or smaller than the distance between two first electrodes.

20. The device structure of claim 15 wherein the dielectric comprises a high-k material, and wherein the electrodes comprise a metallic material.
